(19) United States
(12) Patent Application Publication
(10) Pub. No.: US 2025/0306406 A1
(43) Pub. Date: Oct. 2, 2025

(54) OPTICAL SEMICONDUCTOR DEVICE

(71) Applicant: Lumentum Operations LLC, San Jose, CA (US)

(72) Inventors: Shuhei OHNO, Sagamihara (JP); Takanori SUZUKI, Hachioji (JP)

(21) Appl. No.: 18/902,015

(22) Filed: Sep. 30, 2024

(30) Foreign Application Priority Data
Mar. 28, 2024 (JP) 2024054006
Jul. 8, 2024 (JP) 2024109412

(51) Int. Cl. G02F 1/015; H01S 5/00

(52) U.S. Cl. CPC G02F 1/0155; H01S 5/0085

(57) ABSTRACT

Provided is an optical semiconductor device that has an excellent characteristic. The optical semiconductor device includes: first and second conductivity type semiconductor layers; an optical functional layer; a first electrode including a first pad electrode, the first electrode being connected to the first conductivity type semiconductor layer; and a second electrode including a second pad electrode configured to receive an electric signal as input, the second electrode being connected to the second conductivity type semiconductor layer. The first conductivity type semiconductor layer includes first and second regions, and a high resistance region overlapping the second region. The first region overlaps, an entire region of the first pad electrode. The second region overlaps, an entire region of the second pad electrode. The high resistance region is arranged to avoid the optical functional layer. The high resistance region has an outer edge which divides the first region and the second region.

### CROSS-REFERENCE TO RELATED APPLICATION

This Patent Application claims priority to Japan Patent Application No. JP2024-109412, filed on Jul. 8, 2024, and Japan Patent Application No. JP2024-054006, filed on Mar. 28, 2024. The disclosure of the prior Applications are considered part of and are incorporated by reference into this Patent Application.

### TECHNICAL FIELD

The present disclosure relates generally to an optical semiconductor device.

### BACKGROUND

An optical semiconductor device used in optical communication can include an optical functional layer at which light emission, absorption, or the like, is performed, and two electrodes for inputting electric signals to the optical functional layer. An optical semiconductor device can include two electrodes that are arranged on a same surface of a semiconductor substrate. Further, as a structure of the optical semiconductor device, a buried hetero structure (hereinafter referred to as “BH structure”) can include a mesa structure, in which both sides of the mesa structure are buried with a semiconductor layer.

### SUMMARY

An electrode is required in order to transmit an electric signal input from an external device or the like to an optical functional layer. Further, for connection to the external device, the electrode includes a part having a particular size. This part is called, for example, an electrode pad. This electrode pad also becomes a factor that causes a parasitic capacitance. Here, in order to reduce the parasitic capacitance, a region below the electrode pad can be electrically isolated from another region. For example, after a semiconductor multilayer structure is grown on a semi-insulating substrate, a diffusion region is formed, in which p-type or insulating impurities are diffused from an upper surface of the semiconductor multilayer to the semi-insulating substrate to reduce the parasitic capacitance of the electrode pad (bonding pad). Further, forming a groove having a depth that reaches the semi-insulating substrate around the electrode pad can reduce the parasitic capacitance.

In some cases, the p-type or insulating impurity diffusion region is formed by diffusing impurities from the upper surface of the semiconductor multilayer. Here, in a case of application of a similar forming method to the optical semiconductor device having the BH structure, there is a concern that the following problems are caused. First, when the impurities are diffused from the upper surface of the semiconductor multilayer to a region reaching the semi-insulating substrate, controllability of a diffusion process is low, and, in some cases, the impurities cannot be arranged in a desired region. For example, when the diffusion region does not reach the semi-insulating substrate, there is a fear that a sufficient effect of reducing the parasitic capacitance cannot be obtained. This problem becomes particularly remarkable when the semiconductor multilayer is thick. Next, in order to reduce the parasitic capacitance, it can be effective to bring the diffusion region as close as possible to the optical functional layer. However, when the diffusion region is arranged next to the optical functional layer (in this case, the absorption layer), there is a fear that an optical influence may occur. For example, there are concerns about increase of a light absorption amount caused by the diffusion region.

Further, when the electrode pad is surrounded by a groove, a wiring length from the electrode pad to the mesa structure is increased. In particular, when a groove is used to surround the electrode pad, the electrode is also required to be arranged on a side surface of the groove. A long wiring length increases an inductance component, which is disadvantageous to high-speed operation.

The present invention has an object to provide an optical semiconductor device that is reduced in a parasitic capacitance and has an excellent high-speed operation characteristic.

In some implementation, an optical semiconductor device includes: an insulating semiconductor layer; a first conductivity type semiconductor layer arranged above the insulating semiconductor layer; an optical functional layer arranged above the first conductivity type semiconductor layer, the optical functional layer forming a mesa structure; a second conductivity type semiconductor layer arranged above the optical functional layer; a first electrode including a first pad electrode configured to receive an electric signal as input, the first electrode being connected to the first conductivity type semiconductor layer; and a second electrode including a second pad electrode configured to receive an electric signal as input, the second electrode being connected to the second conductivity type semiconductor layer. The first conductivity type semiconductor layer includes a first region, a second region, and a high resistance region overlapping at least a part of the second region in plan view. The first region overlaps, in plan view, an entire region in plan view of the first pad electrode. The second region overlaps, in plan view, an entire region in plan view of the second pad electrode. The high resistance region is arranged so as to avoid the optical functional layer in plan view. The high resistance region has an outer edge which divides the first region and the second region in plan view.

### BRIEF DESCRIPTION OF THE DRAWINGS

FIG. 1 is a top view of an optical semiconductor device according to a first example implementation of the present invention.

FIG. 2 is a schematic cross-sectional view taken along the line II-II of the optical semiconductor device illustrated in FIG. 1.

FIG. 3A is a schematic cross-sectional view taken along the line III-III of the optical semiconductor device illustrated in FIG. 1.

FIG. 3B is a schematic cross-sectional view taken along the line III-III of the optical semiconductor device illustrated in FIG. 1.

FIG. 3C is a schematic cross-sectional view taken along the line III-III of the optical semiconductor device illustrated in FIG. 1.

FIG. 4 is an explanatory view for illustrating an effect of the first example implementation.

FIG. 5 is a top view of an optical semiconductor device according to Modification Example 1 of the first example implementation.

FIG. 6 is a top view of an optical semiconductor device according to Modification Example 2 of the first example implementation.

FIG. 7 is a top view of an optical semiconductor device according to a second example implementation of the present invention.

FIG. 8 is a schematic cross-sectional view taken along the line VIII-VIII of the optical semiconductor device illustrated in FIG. 7.

FIG. 9 is a top view of an optical semiconductor device according to a third example implementation of the present invention.

FIG. 10 is a schematic cross-sectional view taken along the line X-X of the optical semiconductor device illustrated in FIG. 9.

FIG. 11 is a schematic cross-sectional view taken along the line XI-XI of the optical semiconductor device illustrated in FIG. 9.

FIG. 12 is a top view of an optical semiconductor device according to Modification Example 1 of the third example implementation.

FIG. 13 is a top view of an optical semiconductor device according to Modification Example 2 of the third example implementation.

FIG. 14 is a top view of an optical semiconductor device according to Modification Example 3 of the third example implementation.

FIG. 15 is a top view of an optical semiconductor device according to Modification Example 4 of the third example implementation.

FIG. 16 is a top view of an optical semiconductor device according to a fourth example implementation of the present invention.

FIG. 17 is a schematic cross-sectional view taken along the line XVII-XVII of the optical semiconductor device illustrated in FIG. 16.

FIG. 18 is a top view of an optical semiconductor device according to a fifth example implementation of the present invention.

FIG. 19 is a schematic cross-sectional view taken along the line XIX-XIX of the optical semiconductor device illustrated in FIG. 18.

FIG. 20 is a schematic cross-sectional view taken along the line XX-XX of the optical semiconductor device illustrated in FIG. 18.

FIG. 21 is a top view of an optical semiconductor device according to a modification example of the fifth example implementation.

FIG. 22 is a schematic cross-sectional view taken along the line XXII-XXII of the optical semiconductor device illustrated in FIG. 21.

### DETAILED DESCRIPTION

The following detailed description of example implementations refers to the accompanying drawings. The same reference numbers in different drawings may identify the same or similar elements.

A specific and detailed description is given below on example implementations of the present invention with reference to the drawings. Members denoted by the same reference symbol throughout the drawings have the same or an equivalent function, and a repetitive description on the members is omitted. Note that sizes of graphics are not always to scale.

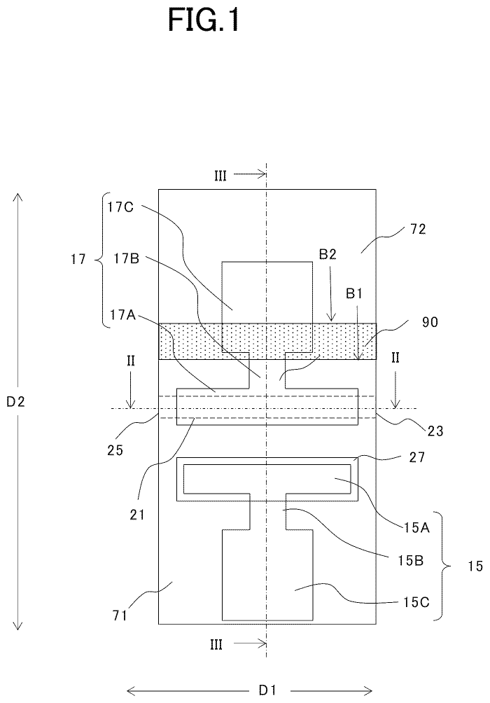

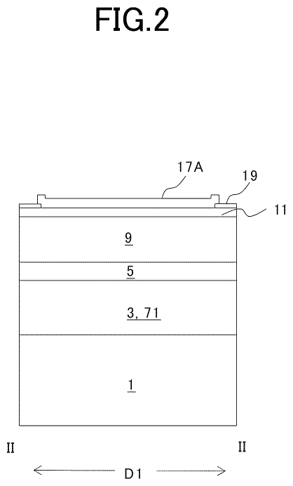

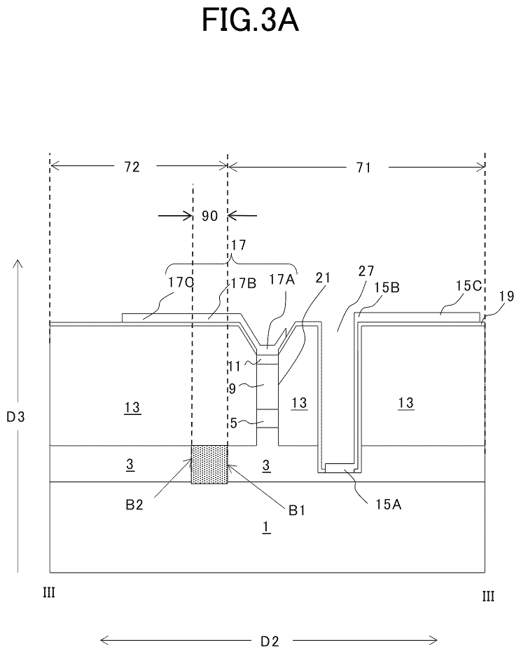

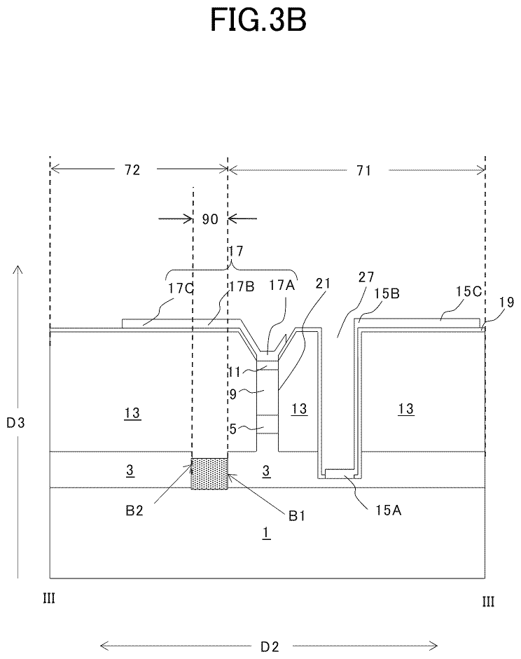

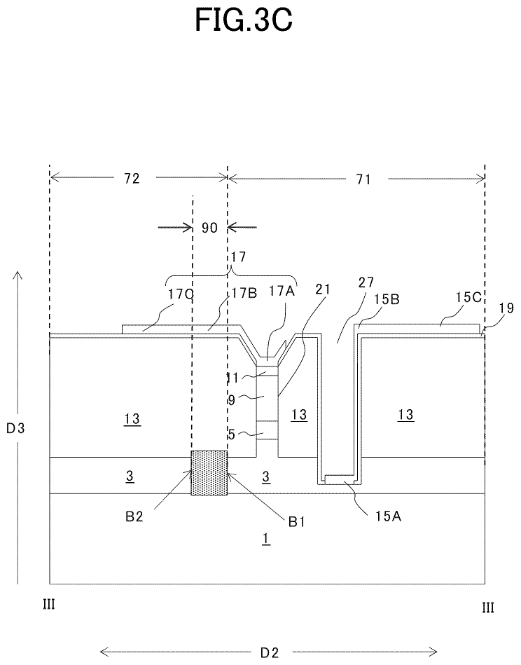

FIG. 1 is a top view of an optical semiconductor device according to a first example implementation of the present invention. FIG. 2 is a cross-sectional view for schematically illustrating a cross section taken along the line II-II of FIG. 1. FIG. 3A is a cross-sectional view for schematically illustrating a cross section taken along the line III-III of FIG. 1.

The optical semiconductor device may be an edge-emitting electro-absorption modulator, a direct-modulation laser, or an edge-illuminated receiver that requires wideband operation. In this case, an electro-absorption modulator is described as an example. The optical semiconductor device may include a first facet 23 and a second facet 25. In this case, light enters the first facet 23. The incident light may be absorbed in accordance with a high-frequency electric signal applied between a first electrode 15 and a second electrode 17, and a high-frequency optical signal may be output from the second facet 25. The incident side and the output side may be reversed. The first facet 23 and the second facet 25 may each be covered with an insulating film for protection and reflectance control.

The optical semiconductor device may include, on a substrate 1, a first conductivity type semiconductor layer 3, an optical functional layer 5, a second conductivity type semiconductor layer 9, and a second conductivity type contact layer 11. Here, the substrate 1 may be an insulating (or semi-insulating) semiconductor substrate. In this case, the first conductivity type semiconductor layer 3 may be an n-type semiconductor layer, and functions as a cladding layer and a layer for contact to the first electrode 15. The first conductivity type semiconductor layer 3 may include a plurality of layers. For example, the first conductivity type semiconductor layer 3 may include a first conductivity type contact layer. That is, the first conductivity type semiconductor layer 3 represents a first conductivity type semiconductor layer for transmitting an electric signal applied to the first electrode 15 to the optical functional layer 5, and may be formed of a plurality of layers or from a plurality of materials. The optical functional layer 5 may include at least multiple quantum wells. In this case, the optical functional layer 5 functions as an absorption layer for absorbing light in accordance with the applied voltage. In this case, the second conductivity type semiconductor layer 9 may be a p-type semiconductor layer, and functions as a cladding layer. The second conductivity type semiconductor layer 9 may include a plurality of layers. The second conductivity type contact layer 11 may be a semiconductor layer connected to the second electrode 17. The conductivity of the second conductivity type contact layer 11 may be higher than the conductivity of the second conductivity type semiconductor layer 9, and the second conductivity type contact layer 11 may be arranged in order to reduce a contact resistance between the second electrode 17 and the semiconductor layer. The second conductivity type contact layer 11 is not required to be arranged. That is, the second conductivity type semiconductor layer 9 represents a second conductivity type semiconductor layer for transmitting an electric signal applied to the second electrode 17 to the optical functional layer 5, and may be formed of a plurality of layers or from a plurality of materials. Further, another layer may be included between the first conductivity type semiconductor layer 3 and the optical functional layer 5 and/or between the second conductivity type semiconductor layer 9 and the optical functional layer 5. For example, an optical confinement layer may be arranged. The substrate 1 is, for example, InP doped with Fe. The first conductivity type semiconductor layer 3 and the second conductivity type semiconductor layer 9 may be each, for example, InP. The optical functional layer 5 may be InGaAsP, and the second conductivity type contact layer 11 may be InGaAs. Those materials are merely examples. Further, the above-mentioned semiconductor layers may be formed so as to extend from the first facet 23 to reach the second facet 25, but the present invention is not limited thereto. A window structure may be arranged on the second facet 25 side of the light output side. When the window structure is included, a mesa structure 21 to be described herein does not reach the second facet 25.

In some cases, another insulating semiconductor layer (for example, a buffer layer) may be arranged between the substrate 1 and the first conductivity type semiconductor layer 3. As another example, in some cases, a conductive substrate may be used as the substrate 1, and after an insulating semiconductor layer is arranged thereon, the first conductivity type semiconductor layer 3 may be arranged thereon. In other words, the first conductivity type semiconductor layer 3 does not represent a layer formed in contact on the substrate 1, but represents a first conductivity type semiconductor layer arranged on an upper side of the insulating semiconductor layer. In the first example implementation, the insulating semiconductor layer may be the substrate 1.

As illustrated in FIG. 3A, the optical semiconductor device may include the mesa structure 21. The mesa structure 21 may include a part of the first conductivity type semiconductor layer 3, the optical functional layer 5, the second conductivity type semiconductor layer 9, and the second conductivity type contact layer 11. The mesa structure 21 extends in a first direction D1. In a second direction D2 orthogonal to the first direction D1 in plan view, a buried layer 13 may be arranged on both side surfaces of the mesa structure 21. The buried layer 13 may be a semiconductor layer. Here, the buried layer 13 may be a semi-insulating semiconductor layer. For example, the buried layer 13 may be InP doped with Fe. The buried layer 13 may have a multilayer structure including a p-type semiconductor layer and an n-type semiconductor layer. The mesa structure 21 may be formed so as to extend from the first facet 23 to the second facet 25. In FIG. 1, an interface between an upper surface of the mesa structure 21 and the buried layer 13 may be indicated by the dotted line. Here, a height from the substrate 1 to an upper surface of the buried layer 13 may be higher than a height from the substrate 1 to the upper surface of the mesa structure 21. An uppermost surface of the buried layer 13 may be a substantially flat surface, but an inclined surface as illustrated in FIG. 3A may be provided in the vicinity of the mesa structure 21. The height from the substrate 1 to the upper surface of the buried layer 13 and the height from the substrate 1 to the upper surface of the mesa structure 21 may be substantially equal to each other.

On the surface of the optical semiconductor device, an insulating film 19 may be arranged except for a part of the surface. The insulating film 19 may be arranged on the upper surface of the buried layer 13. The insulating film 19 may not be arranged in a part of the upper surface of the mesa structure 21. Further, the insulating film 19 may also not arranged in a part of a bottom surface of a trench portion 27 to be described herein.

The optical semiconductor device may include the trench portion 27. The trench portion 27 may be a part dug from the surface of the buried layer 13 to reach the first conductivity type semiconductor layer 3. The trench portion 27 illustrated in FIG. 1 does not reach the first facet 23 and the second facet 25, but the present invention may not be limited thereto. The insulating film 19 may be arranged on a part of a bottom portion of the trench portion 27 and a side surface of the trench portion 27. In the bottom portion of the trench portion 27, the first conductivity type semiconductor layer 3 may be exposed from the insulating film 19. The first conductivity type semiconductor layer 3 and the first electrode 15 may be electrically/physically connected to each other in this exposed region. Further, the side surface of the trench portion 27 is illustrated as a surface perpendicular to the substrate 1, but the present invention is not limited thereto. For example, the side surface may be inclined with respect to the bottom portion of the trench portion 27 so that an upper side of the trench portion 27 becomes wider.

The optical semiconductor device may include the first electrode 15. The first electrode 15 may include a first contact electrode 15A connected to the first conductivity type semiconductor layer 3 at the bottom portion of the trench portion 27. When a first conductivity type contact layer is arranged, the first contact electrode 15A may be connected to the first conductivity type contact layer. In other words, the first contact electrode 15A represents a region of the first electrode 15 physically connected to the first conductivity type semiconductor layer (first conductivity type semiconductor layer 3 or first conductivity type contact layer) electrically connected to the optical functional layer 5. That is, the first contact electrode 15A represents a region of the first electrode 15 connected to the first conductivity type semiconductor layer in order to transmit the electric signal to the optical functional layer 5. The first electrode 15 may include a first pad electrode 15C arranged on the upper surface of the buried layer 13. In addition, the first electrode 15 may include a first bridge electrode 15B connecting the first contact electrode 15A and the first pad electrode 15C to each other. Those three electrodes may be integrally formed. In the first direction D1, the first pad electrode 15C may be longer than the first bridge electrode 15B. The first pad electrode 15C requires a certain area because the first pad electrode 15C may be connected to a wire or wiring for connection to an external device or the like. In other words, the first pad electrode 15C represents a region at which electrical connection to outside of the first electrode 15 is to be established. In this case, the first pad electrode 15C may have a rectangular shape, but the present invention is not limited thereto. The first pad electrode 15C may have any one of a circular shape, an elliptical shape, a rounded rectangular shape, or a polygonal shape. When the length in the first direction D1 described above is defined, the length may be defined at the longest portion. The first bridge electrode 15B may be desired to be as small as possible because the first bridge electrode 15B becomes a cause of occurrence of a parasitic capacitance. Accordingly, the first bridge electrode 15B may have a shortest shape in the first direction D1.

The optical semiconductor device may include the second electrode 17. In the first example implementation, in the second direction D2, the first electrode 15 and the second electrode 17 may be arranged on the right and the left of the mesa structure 21. The second electrode 17 may include a second contact electrode 17A connected to the second conductivity type contact layer 11 on the upper surface of the mesa structure 21. When no second conductivity type contact layer 11 is arranged, the second contact electrode 17A may be connected to the second conductivity type semiconductor layer 9. In other words, the second contact electrode 17A represents a region of the second electrode 17 physically connected to the second conductivity type semiconductor layer (second conductivity type semiconductor layer 9 or second conductivity type contact layer 11) electrically connected to the optical functional layer 5. This state is referred to as, in a wide sense, “the second contact electrode 17A (second electrode 17) is connected to the second conductivity type semiconductor layer 9.” The second electrode 17 may include a second pad electrode 17C arranged on the upper surface of the buried layer 13. In addition, the second electrode 17 may include a second bridge electrode 17B connecting the second contact electrode 17A and the second pad electrode 17C to each other. Those three electrodes may be integrally formed. As illustrated in FIG. 2, a connection region between the second contact electrode 17A and the second conductivity type contact layer 11 does not extend across the entire optical functional layer 5 in the first direction D1, but the present invention is not limited thereto. The connection region may extend across the entire optical functional layer 5. In the first direction D1, the second pad electrode 17C may be longer than the second bridge electrode 17B. The second pad electrode 17C requires a certain area because the second pad electrode 17C may be connected to a wire or wiring for connection to an external device or the like. In other words, the second pad electrode 17C represents a region at which electrical connection to outside of the second electrode 17 is to be established. In this case, the second pad electrode 17C may have a rectangular shape, but the present invention is not limited thereto. The second pad electrode 17C may have any one of a circular shape, an elliptical shape, a rounded rectangular shape, or a polygonal shape. When the length in the first direction D1 described above is defined, the length may be defined at the longest portion. Further, the first pad electrode 15C and the second pad electrode 17C may be desired to have the same surface area, but the present invention is not limited thereto. The second bridge electrode 17B may be desired to be as small as possible because the second bridge electrode 17B becomes a cause of occurrence of a parasitic capacitance. Accordingly, the second bridge electrode 17B may have the thinnest shape in the first direction D1. The first electrode 15 and the second electrode 17 may each be a metal layer, and may have the same material and layer structure or different materials and layer structures.

The optical semiconductor device may include a first region 71, a second region 72, and a high resistance region 90 overlapping at least a part of the second region 72 in plan view. The high resistance region 90 does not overlap the optical functional layer 5 in plan view. In other words, the high resistance region 90 is arranged so as to avoid the optical functional layer in plan view. In a third direction D3, an upper surface of the high resistance region 90 may be arranged on the substrate 1 side with respect to a lower surface of the optical functional layer 5. Here, the third direction D3 indicates a direction in which the semiconductor layer may be grown with respect to the surface of the substrate 1 (that is, a direction normal to the surface of the substrate 1). Further, the upper surface of the high resistance region 90 may be flush with an interface between the first conductivity type semiconductor layer 3 and the buried layer 13. As illustrated in FIG. 3B, as long as the upper surface of the high resistance region 90 is on the lower side with respect to the lower surface of the optical functional layer 5, the upper surface of the high resistance region 90 may be positioned lower than the interface between the first conductivity type semiconductor layer 3 and the buried layer 13. Further, as illustrated in FIG. 3C, the upper surface of the high resistance region 90 may be positioned higher than the interface between the first conductivity type semiconductor layer 3 and the buried layer 13. An outer edge of the high resistance region 90 in the second direction D2 may be an interface between the first conductivity type semiconductor layer 3 and the high resistance region 90. Out of outer edges of the high resistance region 90 in the second direction D2, an interface which is an outer edge closer to the mesa structure 21 may be referred to as “first interface B1,” and an interface on the opposite side may be referred to as “second interface B2.” Here, the first interface B1 overlaps the second bridge electrode 17B in plan view. Further, the second interface B2 overlaps the second pad electrode 17C in plan view. The second interface B2 may also overlap the second bridge electrode 17B. In the first direction D1, the high resistance region 90 extends from the first facet 23 to reach the second facet 25. Here, for the sake of description, FIG. 1 shows a transparent view of the high resistance region 90. In an actual case, as illustrated in FIG. 3A, the high resistance reagion 90 does not appear on the surface of the optical semiconductor device, and may be arranged below the buried layer 13. The high resistance region 90 may be arranged to divide the first conductivity type semiconductor layer 3. The first region 71 may be a region of the first conductivity type semiconductor layer 3 on the first pad electrode 15C side with respect to the first interface B1, and overlaps the entire region of the first pad electrode 15C electrically connected to the optical functional layer 5 in plan view. The second region 72 may be a region of the first conductivity type semiconductor layer 3 on the second pad electrode 17C side with respect to the first interface B1, and overlaps the entire region of the second pad electrode 17C in plan view. The first contact electrode 15A may be connected to the first conductivity type semiconductor layer 3 in the first region 71. Here, a width (length in the second direction D2) of the high resistance region 90 may be freely selected as long as electrical isolation can be achieved between the first region 71 and the second region 72 excluding the high resistance region 90. For example, the width of the high resistance region 90 may be several tens of micrometers.

The high resistance region 90 may be formed by doping a part of the first conductivity type semiconductor layer 3 (region that finally becomes the high resistance region 90) with second conductivity type or insulating impurities. For example, when the first conductivity type semiconductor layer 3 may be the “n” type, the high resistance region 90 may be formed by doping through diffusion of Zn, which may be a p-type dopant. At this time, in the second direction D2, the second region 72 (including the high resistance region 90) and the first region 71 may have an npn structure, and thus forward bias and reverse bias currents may be both prevented from flowing. That is, the first region 71 and the second region 72 excluding the high resistance region 90 may be brought to a state of being electrically isolated from each other. Further, doping with insulating impurities causes a part of the first conductivity type semiconductor layer 3 to become insulated or semi-insulated. Here, “becoming insulated or semi-insulated” represents becoming a region having a resistance to the extent that sufficient electrical insulation can be achieved between the first region 71 and the second region 72 excluding the high resistance region 90.

As another forming method, the high resistance region 90 may be formed by re-growing a second conductivity type semiconductor layer or a semi-insulating semiconductor layer. Although the manufacturing method is not limited, for example, after the first conductivity type semiconductor layer 3 is formed on the substrate 1, the first conductivity type semiconductor layer 3 in a region that becomes the high resistance region 90 thereafter may be removed. It may be only required that, in the removed region, a second conductivity type or semi-insulating semiconductor layer be re-grown. It may be preferred that this re-grown semiconductor layer (that is, the semiconductor layer for forming the high resistance region 90) and the first conductivity type semiconductor layer 3 be formed of the same material. The material is, for example, InP. Here, being formed of the same material means that, except for the material used for doping, the basic composition (in this case, InP) may be the same. In the case of this forming method, the upper surface of the high resistance region 90 in the third direction D3 may not always be flush with the upper surface of the first conductivity type semiconductor layer 3. Thus, as illustrated in FIG. 3B and FIG. 3C, the upper surface of the high resistance region 90 may be positioned higher or lower than the upper surface of the first conductivity type semiconductor layer 3. The buried layer 13 may be formed to be arranged on the high resistance region 90 after the high resistance region 90 may be formed.

A lower surface of the high resistance region 90 in the third direction D3 may be on the substrate 1 side with respect to a lower surface of the first conductivity type semiconductor layer 3. For example, when the high resistance region 90 formed by diffusing impurities, it may be preferred that the impurities be deeply diffused until the impurities reach the substrate 1 so that the first conductivity type semiconductor layer 3 can be reliably divided into the first region 71 and the second region 72 excluding the high resistance region 90. Further, even when the high resistance region 90 is formed by re-growth, it may be preferred that over-etching be performed until the substrate 1 is shaved a little in order to prevent the first conductivity type semiconductor layer 3 from remaining when the region that becomes the high resistance region 90 of the first conductivity type semiconductor layer 3 (region for re-growth) may be removed. As a result, the lower surface of the high resistance region 90 may be on the substrate 1 side with respect to the lower surface of the first conductivity type semiconductor layer 3. Further, the lower surface of the high resistance region 90 may not always required to be on the substrate 1 side with respect to the lower surface of the first conductivity type semiconductor layer 3, and may be flush with the lower surface of the first conductivity type semiconductor layer 3.

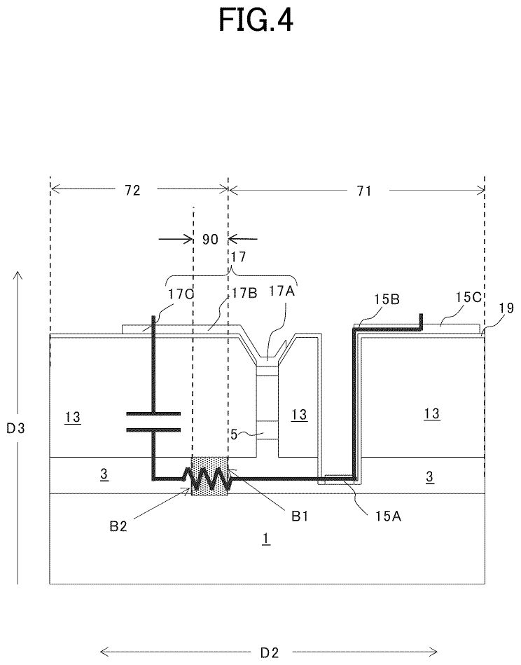

The reason why the parasitic capacitance of the electrode may be reduced by the high resistance region 90 is described with reference to FIG. 4. In the first example implementation, a parasitic capacitance caused by a part of the second bridge electrode 17B and the second pad electrode 17C may be reduced by the high resistance region 90. For the sake of easy description, the second pad electrode 17C may be used for description. An electric signal may be applied between the first electrode 15 and the second electrode 17. At this time, a voltage may be applied between the second pad electrode 17C and the first conductivity type semiconductor layer 3. The insulating film 19 and the buried layer 13 may be arranged below the second pad electrode 17C. Those layers may be insulating/semi-insulating layers, and hence a part between the second pad electrode 17C and the first conductivity type semiconductor layer 3 may function as a capacitor. This capacitor hinders high-speed operation. Here, the high resistance region 90 may be arranged between the region of the first conductivity type semiconductor layer 3 below the second pad electrode 17C (region excluding the high resistance region 90 within the second region 72) and the region (first region 71) of the first conductivity type semiconductor layer 3 electrically connected to the first electrode 15. Thus, the region excluding the high resistance region 90 within the second region 72 may be in fact electrically isolated from an electrical path between the first electrode 15 and the second electrode 17 via the mesa structure 21. In other words, the high resistance region 90 causes the region of the first conductivity type semiconductor layer 3 below the second pad electrode 17C (region excluding the high resistance region 90 within the second region 72) to be electrically isolated from the first conductivity type semiconductor layer 3 (first region 71) below the second contact electrode 17A electrically connected to the mesa structure 21. Accordingly, the parasitic capacitance caused by the second pad electrode 17C may have no influence at the time of actual drive. As a result, an optical semiconductor device adapted to high-speed operation may be achieved. In the following, although the parasitic capacitance itself may not be eliminated in a strict sense, the parasitic capacitance may be referred to as being reduced because the parasitic capacitance has no influence at the time of actual drive. For example, when the first conductivity type is the “n” type and the high resistance region 90 is a p-type semiconductor layer (second conductivity type semiconductor layer) including p-type impurities, also in the second pad electrode 17C in the region overlapping the high resistance region 90 in plan view, the occurrence of the parasitic capacitance may be suppressed. More strictly speaking, in the case of reverse bias drive, a parasitic capacitance caused by the second electrode 17 overlapping a region from the first interface B1 toward a side surface of the optical semiconductor device (case of toward a side opposite to the mesa structure 21) may be reduced. In the case of forward bias, a parasitic capacitance caused by the second electrode 17 overlapping the first conductivity type semiconductor layer 3 positioned on the outer side of the optical semiconductor device with respect to the second interface B2 may be reduced. When the high resistance region 90 is an insulating/semi-insulating semiconductor layer, regardless of a direction of an applied bias, a parasitic capacitance (parasitic capacitance caused by the second bridge electrode 17B overlapping the first conductivity type semiconductor layer 3) may be reduced. The second bridge electrode 17B may become a cause of occurrence of the parasitic capacitance as well, but, as described above, depending on the direction of the applied bias and whether the high resistance region 90 may be conductive or semi-insulated, the parasitic capacitance may be reduced in some cases, and the parasitic capacitance cannot be reduced in other cases. Further, in the first example implementation, the buried layer 13 may be also a region that may have a high resistance enough as compared to the second conductivity type semiconductor layer 9 or the like, and hence spread of an electric field within the buried layer 13 may be little. Thus, a parasitic capacitance reduction effect equivalent to that in the case in which the high resistance region 90 is formed up to the upper surface of the buried layer 13 may be obtained.

Further, in the first example implementation, the buried layer 13 may not be damaged because the high resistance region 90 may be formed by diffusing impurities from the top of the buried layer 13 (semiconductor layer). That is, the buried layer 13 does not include the high resistance region 90. Moreover, the high resistance region 90 may not be arranged at the same height as that of the optical functional layer 5 in the third direction D3. In some cases, the impurity diffusion region may be arranged beside an active region corresponding to the optical functional layer 5. The positional accuracy of impurity diffusion may not be so high. When the impurities are diffused to the optical functional layer 5 as well, the characteristic and reliability of the optical functional layer 5 may be greatly degraded. In order to avoid this situation, the impurity diffusion region may be required to be kept away from the mesa structure. As the diffusion region is positioned farther from the mesa structure, in accordance therewith, the effect of reducing the parasitic capacitance is decreased (because the region in which the second electrode 17 overlaps the first region 71 of the first conductivity type semiconductor layer 3 in plan view increases). However, in the first example implementation, the high resistance region 90 may not be arranged beside the optical functional layer 5 at the same height. The upper surface of the high resistance region 90 in the third direction D3 may be arranged on the substrate 1 side with respect to the lower surface of the optical functional layer 5. Accordingly, there may be no possibility that the high resistance region 90 affects the optical functional layer 5, and hence the high resistance region 90 may be brought close to the optical functional layer 5 (mesa structure 21) in the second direction D2. Specifically, the first interface B1 between the high resistance region 90 and the first region 71 of the first conductivity type semiconductor layer 3 may be brought close to a position overlapping the second bridge electrode 17B in plan view. In the first example implementation, the buried layer 13 may have an inclined region in contact with the mesa structure 21 and a flat region on the outer side of the inclined region, but the high resistance region 90 may be arranged so as to avoid the inclined region in plan view. However, the high resistance region 90 may be arranged in a region overlapping the inclined region. For example, in the second direction D2, an interval between the first interface B1 and the mesa structure 21 may be preferably 5 μm or more and 40 μm or less, more preferably 15 μm or more and 25 μm or less. However, the dimensions are merely an example.

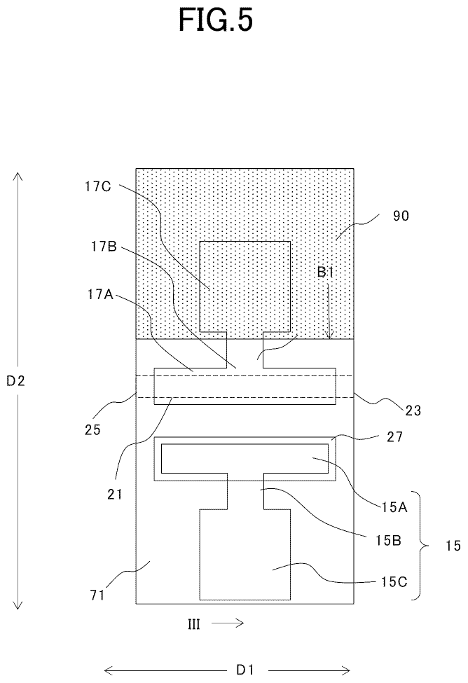

FIG. 5 is a top view of an optical semiconductor device according to Modification Example 1 of the first example implementation. The difference from the first example implementation resides in that the high resistance region 90 may be arranged from the first interface B1 to reach the side surface of the optical semiconductor device. That is, in Modification Example 1, the high resistance region 90 may be the entire region of the second region 72. Also in Modification Example 1, a parasitic capacitance caused by the second pad electrode 17C may be reduced. However, as described above, when the first conductivity type is the “n” type and the high resistance region is the p-type semiconductor layer, the effect of reducing the parasitic capacitance cannot be obtained at the time of forward bias drive. As a matter of course, at the time of reverse bias drive or when the high resistance region 90 is a semi-insulating semiconductor layer, the effect of reducing the parasitic capacitance may be obtained. In Modification Example 1, the outer edge of the high resistance region 90 divides the first region 71 and the second region 72 in plan view.

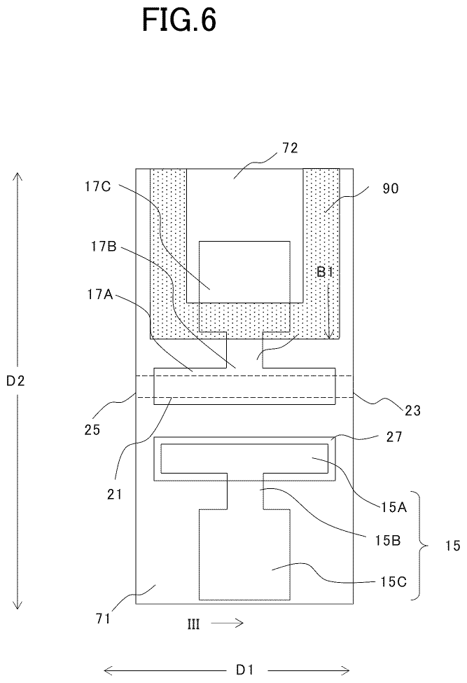

FIG. 6 is a top view of an optical semiconductor device according to Modification Example 2 of the first example implementation. The difference from the first example implementation resides in the shape of the high resistance region 90. In Modification Example 2, the high resistance region 90 may have a U-shape in which a curved portion is linear in plan view. Here, the second region 72 may be a region surrounded by the outer edge (first interface B1) of the high resistance region 90 and the side surface of the optical semiconductor device. Even in Modification Example 2, the first region 71 and the second region 72 excluding the high resistance region 90 may be electrically isolated from each other by the outer edge (first interface B1) of the high resistance region 90, and thus the parasitic capacitance caused by the second pad electrode 17C may be reduced. The high resistance region 90 may be arranged in an L-shape in plan view. For example, the L-shape may be obtained by, in FIG. 6, extending, on the second facet 25 side of the high resistance region 90, the high resistance region 90 to reach the second facet 25 similarly to the first example implementation, and omitting the region extending to the side surface of the optical semiconductor device instead.

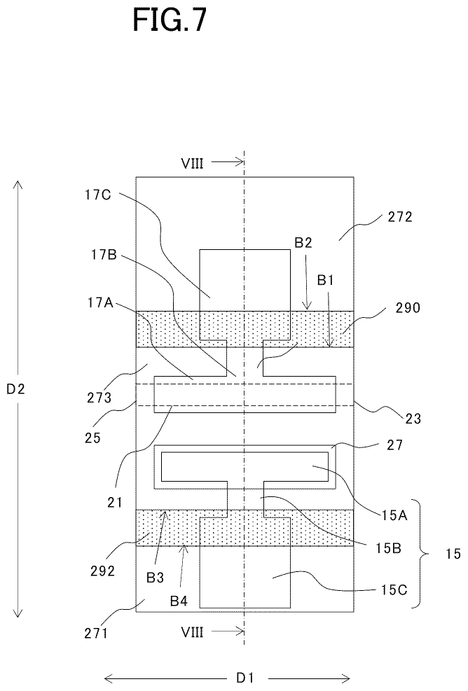

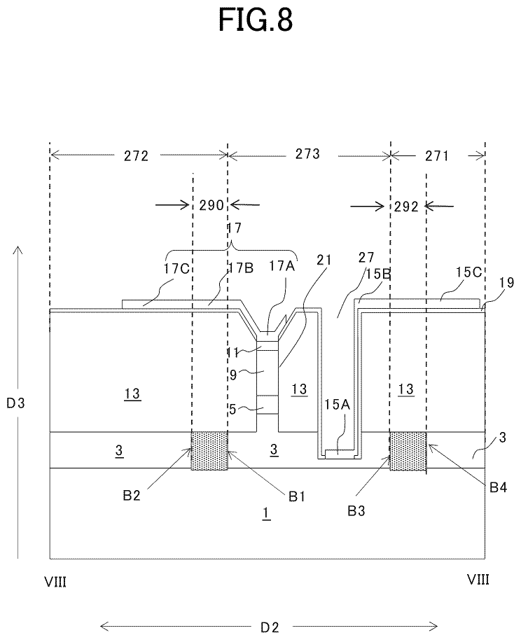

FIG. 7 is a top view of an optical semiconductor device according to a second example implementation of the present invention. FIG. 8 is a cross-sectional view for schematically illustrating a cross section taken along the line VIII-VIII of FIG. 7. The difference from the first example implementation resides in including two high resistance regions.

The optical semiconductor device may include a first high resistance region 290. Here, the first high resistance region 290 may be the same as the high resistance region 90 in the first example implementation. The optical semiconductor device may include a second high resistance region 292. The second high resistance region 292 overlaps a part of the first electrode 15 in plan view. More specifically, the second high resistance region 292 may be arranged for electrical isolation of the first conductivity type semiconductor layer 3 similarly to the first high resistance region 290. A third interface B3 between the second high resistance region 292 and the first conductivity type semiconductor layer 3 on the mesa structure side overlaps the first bridge electrode 15B in plan view. Out of the interfaces between the second high resistance region 292 and the first conductivity type semiconductor layer 3, a fourth interface B4 on a side opposite to the third interface B3 overlaps the first pad electrode 15C in plan view. The second high resistance region 292 extends from the first facet 23 to reach the second facet 25. Other features may be the same as those of the first high resistance region 290.

With the first high resistance region 290 and the second high resistance region 292, the first conductivity type semiconductor layer 3 may be electrically divided into three regions. A third region 273 may be a region that may be below the mesa structure 21 and becomes an electrical path at the time of drive of the optical functional layer 5. A first region 271 may be a region isolated from the third region 273 by the second high resistance region 292. A second region 272 may be a region isolated from the third region 273 by the first high resistance region 290. The effects of the first high resistance region 290 may be the same as the effects described in the first example implementation. The second high resistance region 292 can reduce a parasitic capacitance caused by a part of the first bridge electrode 15B and the first pad electrode 15C. The mechanism thereof may be the same as that of the parasitic capacitance reduction for the second electrode 17.

The second example implementation achieves an optical semiconductor device that may be reduced in the parasitic capacitance caused by the first electrode 15 in addition to the second electrode 17, and may be excellent in high-speed responsiveness. The first high resistance region 290 may not be required to be arranged, and only the second high resistance region 292 may be arranged. Further, the modes of the high resistance region 90 described in the modification examples of the first example implementation may be applied to the first high resistance region 290 or the second high resistance region 292.

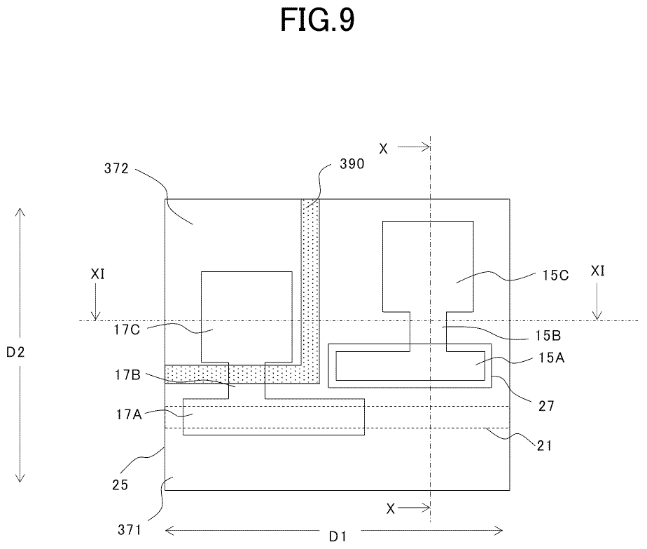

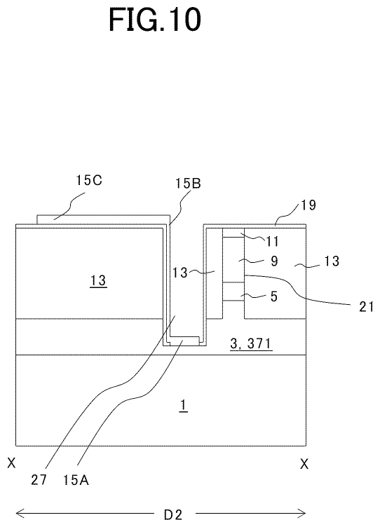

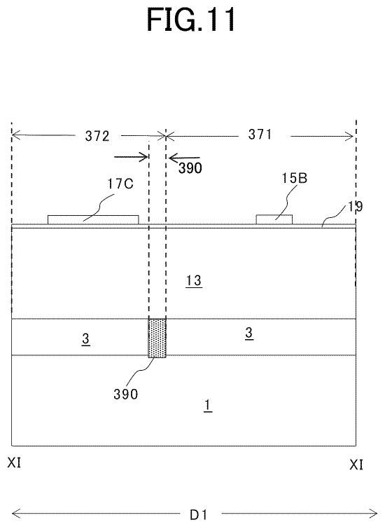

FIG. 9 is a top view of an optical semiconductor device according to a third example implementation of the present invention. FIG. 10 is a cross-sectional view for schematically illustrating a cross section taken along the line X-X of FIG. 9. FIG. 11 is a cross-sectional view for schematically illustrating a cross section taken along the line XI-XI of FIG. 9.

In the third example implementation, the trench portion 27 may be arranged so that its longitudinal direction extends along the first direction D1, and may be arranged in a region in which the position in the second direction D2 overlaps the second bridge electrode 17B and the second pad electrode 17C. In other words, as viewed from the mesa structure 21, the first electrode 15 and the second electrode 17 may be arranged on the same side in the second direction D2. Further, the mesa structure 21 may not be arranged at the middle of the optical semiconductor device in the second direction D2. In the third example implementation, the buried layer 13 and the mesa structure 21 may have substantially equal heights from the substrate 1. The buried layer 13 may be higher than the mesa structure 21, similarly to the first example implementation.

A high resistance region 390 may be arranged in an L-shape so as to surround the second pad electrode 17C in plan view. The high resistance region 390 may be arranged so as to overlap only the second bridge electrode 17B within the second electrode 17, but a part of the high resistance region 390 may overlap the second pad electrode 17C. Similarly to the first example implementation, an outer edge of the high resistance region 390 electrically isolates a first region 371 and a second region 372 from each other. In this case, the first region 371 may be electrically connected to the mesa structure 21. With the third example implementation, a parasitic capacitance caused by the second electrode 17, particularly, the second pad electrode 17C may be reduced. The high resistance region 390 has, in plan view, a width in the second direction D2 narrower than that of the high resistance region 90 in the first example implementation.

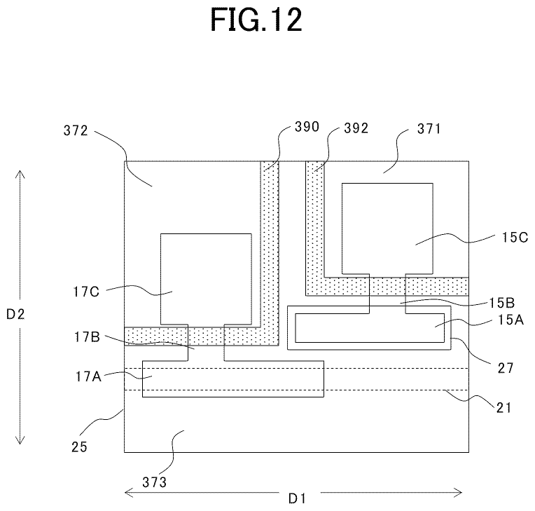

FIG. 12 is a top view of an optical semiconductor device according to Modification Example 1 of the third example implementation. The difference from the third example implementation resides in including a second high resistance region 392. The second high resistance region 392 may be arranged in an L-shape so as to surround the first pad electrode 15C in plan view. With the second high resistance region 392, the first conductivity type semiconductor layer 3 may include a third region 373 electrically isolated from the first region 371. The second high resistance region 392 may overlap the first pad electrode 15C in plan view. In Modification Example 1, outer edges of the high resistance region 390 and the second high resistance region 392 divide the first conductivity type semiconductor layer 3 into the first region 371, the second region 372, and the third region 373. Modification Example 1 can obtain not only the effect of reducing the parasitic capacitance of the second electrode 17, but also the effect of reducing the parasitic capacitance of the first electrode 15.

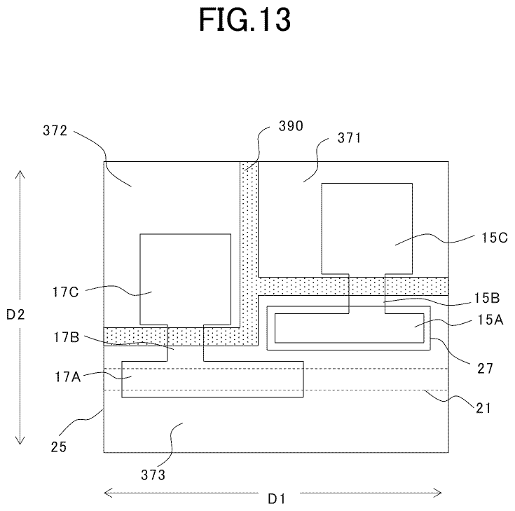

FIG. 13 is a top view of an optical semiconductor device according to Modification Example 2 of the third example implementation. The difference from Modification Example 1 of the third example implementation resides in that the high resistance region 390 and the second high resistance region 392 may be integrally formed. That is, the outer edge of one high resistance region 390 divides the first conductivity type semiconductor layer 3 into the first region 371, the second region 372, and the third region 373. At least a part of the second electrode 17 overlaps the second region 372 in plan view. At least a part of the first electrode 15 overlaps the first region 371 in plan view. In Modification Example 2, effects similar to those of Modification Example 1 may be obtained.

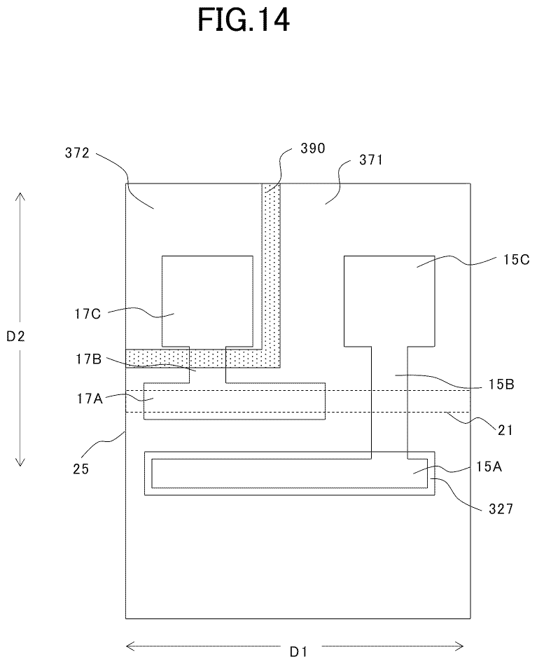

FIG. 14 is a top view of an optical semiconductor device according to Modification Example 3 of the third example implementation. The difference from the third example implementation resides in that a trench portion 327 and the second pad electrode 17C may be arranged across the mesa structure 21. As shown in Modification Example 3, a region in which the first conductivity type semiconductor layer 3 and the first electrode 15 are connected to each other may be on any side of the mesa structure 21 in the second direction D2.

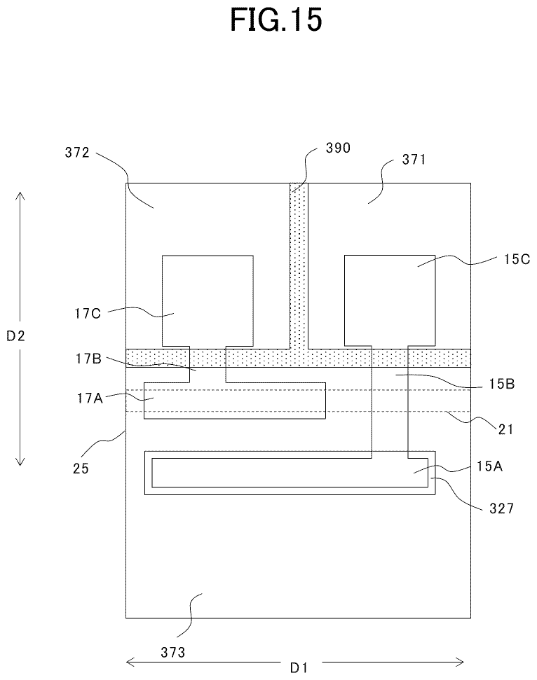

FIG. 15 is a top view of an optical semiconductor device according to Modification Example 4 of the third example implementation. The difference from Modification Example 3 of the third example implementation resides in that the high resistance region 390 may have a T-shape in plan view. The outer edge of the high resistance region 390 divides the first conductivity type semiconductor layer 3 into the first region 371, the second region 372, and the third region 373. Even in Modification Example 4, parasitic capacitances caused by the first electrode 15 and the second electrode 17 may be reduced. As in Modification Example 1, two high resistance regions may be arranged separately from each other. As described above, the shape of the high resistance region may have various modes depending on the arrangement of the electrode, or the like. The high resistance region may be only required to be arranged for electrical isolation of the first conductivity type semiconductor layer 3. Each side for forming the first region, the second region, or the third region as described so far may be not only the interface between the high resistance region and the first conductivity type semiconductor layer, but also a facet or a side surface of the optical semiconductor device.

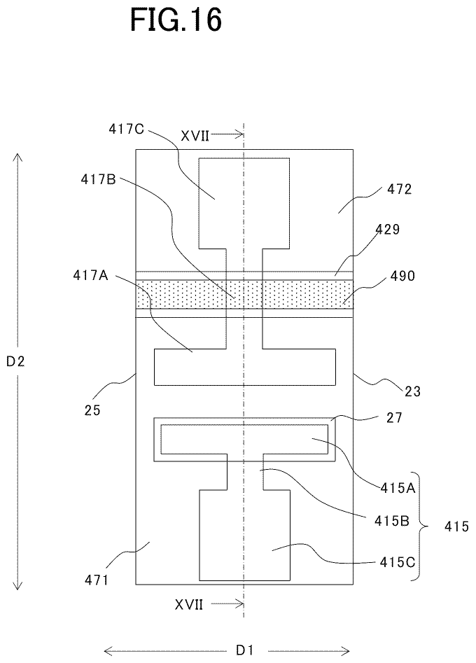

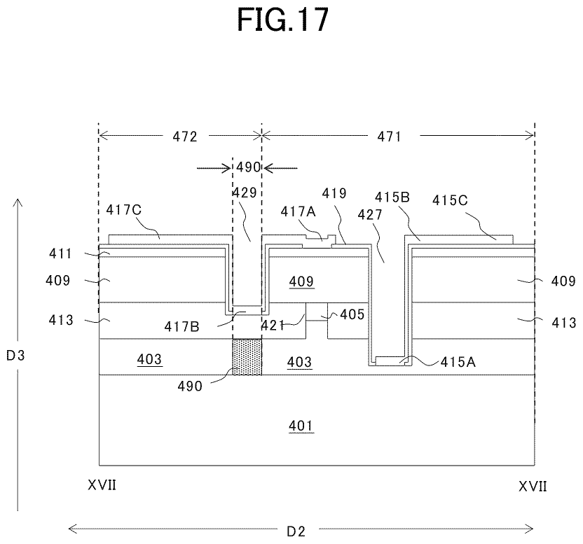

FIG. 16 is a top view of an optical semiconductor device according to a fourth example implementation of the present invention. FIG. 17 may be a cross-sectional view for schematically illustrating a cross section taken along the line XVII-XVII of FIG. 16.

The optical semiconductor device may be a buried type optical semiconductor device called a PBH type. The optical semiconductor device may include, on a substrate 401, a first conductivity type semiconductor layer 403, an optical functional layer 405, a second conductivity type semiconductor layer 409, and a second conductivity type contact layer 411. Here, the substrate 401 may be an insulating (semi-insulating) semiconductor substrate. In this case, the first conductivity type semiconductor layer 403 may be an n-type semiconductor layer, and functions as a cladding layer and a layer for contact to a first electrode 415. The first conductivity type semiconductor layer 403 may include a plurality of layers. The optical functional layer 405 may include at least multiple quantum wells. In this case, the optical functional layer 405 functions as an absorption layer for absorbing light in accordance with the voltage applied thereto. In this case, the second conductivity type semiconductor layer 409 may be a p-type semiconductor layer, and functions as a cladding layer. The second conductivity type semiconductor layer 409 may include a plurality of layers. The second conductivity type contact layer 411 may be a semiconductor layer connected to a second electrode 417. The conductivity of the second conductivity type contact layer 411 may be higher than the conductivity of the second conductivity type semiconductor layer 409, and may be arranged in order to reduce a contact resistance between the second electrode 417 and the semiconductor layer. The second conductivity type contact layer 411 is not required to be arranged.

As illustrated in FIG. 17, the optical semiconductor device may include a mesa structure 421. The mesa structure 421 may include a part of the first conductivity type semiconductor layer 403 and the optical functional layer 405. The mesa structure 421 extends in the first direction D1. In the second direction D2 orthogonal to the first direction D1 in plan view, a buried layer 413 may be arranged on both side surfaces of the mesa structure 421. The buried layer 413 may be a semiconductor layer. Here, the buried layer 413 may have a multilayer structure of a plurality of layers including a p-type semiconductor layer and a n-type semiconductor layer, and forms an electrical block layer (high resistance layer). The mesa structure 421 may be formed so as to extend from the first facet 23 to the second facet 25 in the first direction D1. The second conductivity type semiconductor layer 409 and the second conductivity type contact layer 411 may be arranged on upper surfaces of the mesa structure 421 and the buried layer 413. The mesa structure 421 may include a second conductivity type semiconductor layer on the optical functional layer 405.

In the vicinity of the surface of the optical semiconductor device, an insulating film 419 may be arranged except for a part of the region. The insulating film 419 may be arranged on an upper surface of the second conductivity type contact layer 411. The insulating film 419 may not be arranged in a part above the mesa structure 421. Further, the insulating film 419 may be also not arranged in a part of a bottom surface of a first trench portion 427 to be described later.

The optical semiconductor device may have the first trench portion 427. The first trench portion 427 may be a part dug from the surface of the semiconductor multilayer to reach the first conductivity type semiconductor layer 403. The first trench portion 427 does not reach the first facet 23 and the second facet 25, but the present invention may not be limited thereto. In the bottom surface of the first trench portion 427, the first conductivity type semiconductor layer 403 and the first electrode 415 may be electrically/physically connected to each other. The optical semiconductor device may have a second trench portion 429. The second trench portion 429 may be a groove extending from the surface of the semiconductor multilayer to reach the buried layer 413. The second trench portion 429 reaches the first facet 23 and the second facet 25. The second trench portion 429 may have a depth that divides at least the second conductivity type semiconductor layer 409. The insulating film 419 may be arranged on a part of a bottom surface of the second trench portion 429.

The optical semiconductor device may include the first electrode 415. The first electrode 415 may include three parts similarly to the first example implementation. The optical semiconductor device may include the second electrode 417. The second electrode 417 may include three parts similarly to the first example implementation. A second bridge electrode 417B may be arranged along a side surface and the bottom surface of the second trench portion 429.

The optical semiconductor device may include a high resistance region 490. In the third direction D3, an upper surface of the high resistance region 490 may be arranged on the substrate 401 side with respect to a lower surface of the optical functional layer 405. Further, a lower surface of the high resistance region 490 may be substantially flush with a lower surface of the first conductivity type semiconductor layer 403. However, similarly to the first example implementation, the lower surface of the high resistance region 490 may be arranged on the substrate 1 side with respect to the lower surface of the first conductivity type semiconductor layer 403. The high resistance region 490 may overlap the second bridge electrode 417B in plan view. The high resistance region 490 may overlap the second trench portion 429 in plan view. The high resistance region 490 may have a width wider than that of the second trench portion 429 in the second direction D2.

Even in the fourth example implementation, the effects described above may be obtained. Further, the fourth example implementation may be combined with the modification examples described in other embodiments. As described above, even in the PBH type in which the second conductivity type semiconductor layer is widely arranged on the upper surface of the mesa structure, the effects of the present invention may be obtained.

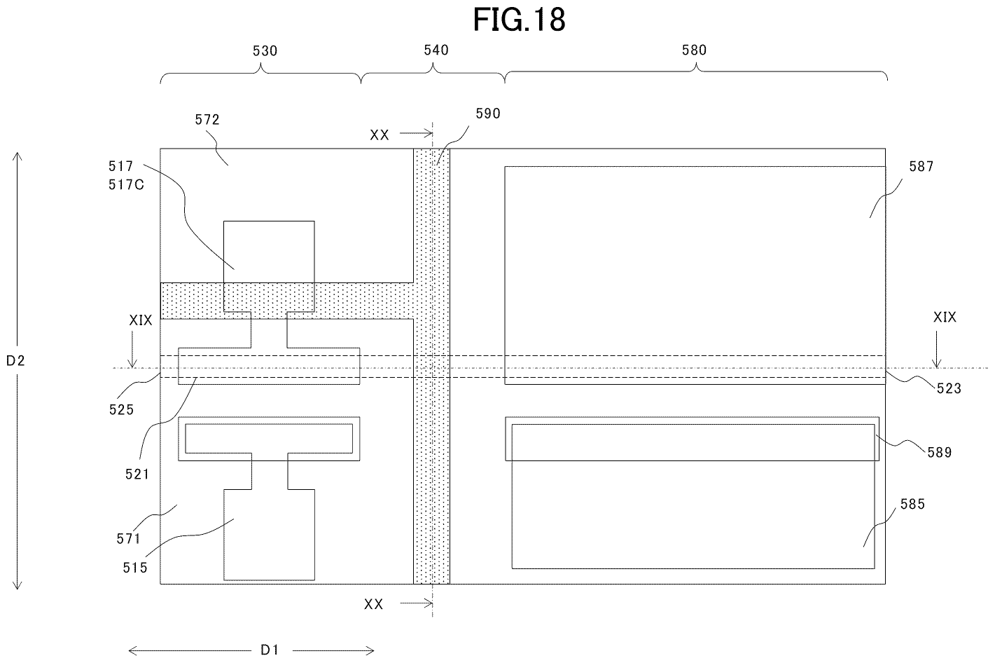

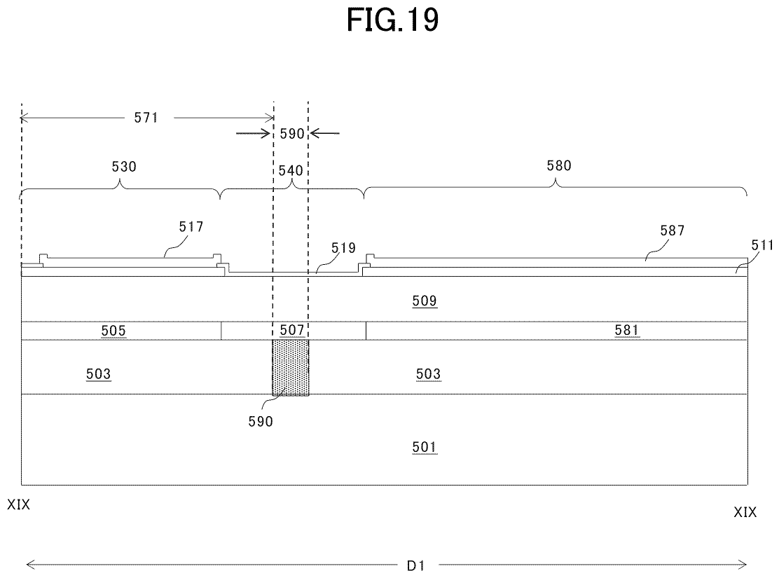

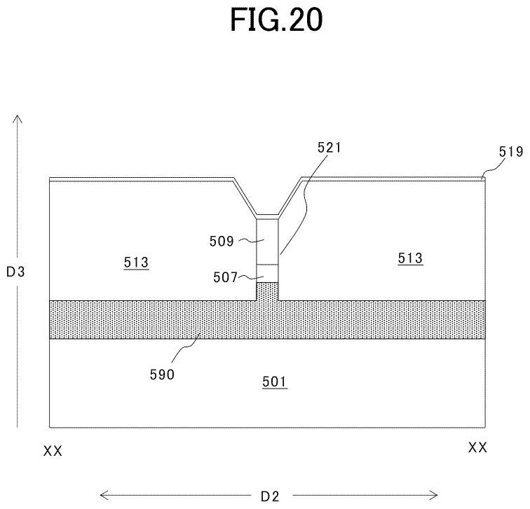

FIG. 18 is a top view of an optical semiconductor device according to a fifth example implementation of the present invention. FIG. 19 is a cross-sectional view for schematically illustrating a cross section taken along the line XXI-XXI of FIG. 18. FIG. 20 is a cross-sectional view for schematically illustrating a cross section taken along the line XX-XX of FIG. 18.

In the optical semiconductor device, a modulator unit 530, a waveguide unit 540, and a semiconductor laser unit 580 may be integrated on a substrate 501 integrally. The semiconductor laser unit 580 outputs continuous light. The waveguide unit 540 transmits output light of the semiconductor laser unit 580 to the modulator unit 530. A first facet 523 may be also a facet of the semiconductor laser unit 580, and may have a high reflection film (not shown) formed thereon. The first facet 523 may have a low reflection film formed thereon. The second facet 525 may have a low reflection film (not shown) formed thereon. The modulator unit 530 and the waveguide unit 540 may be optically connected to each other by butt joint connection, and the waveguide unit 540 and the semiconductor laser unit 580 may be also optically connected to each other by butt joint connection. Here, the modulator unit 530 may have the same structure as that of the optical semiconductor device of the first example implementation.

The semiconductor laser unit 580 may include, on the substrate 501, a first conductivity type semiconductor layer 503, an active layer 581, a second conductivity type semiconductor layer 509, and a second conductivity type contact layer 511. The first conductivity type semiconductor layer 503 and the second conductivity type semiconductor layer 509 of the semiconductor laser unit 580 may be formed in the same layers as the first conductivity type semiconductor layer 503 and the second conductivity type semiconductor layer 509 of the modulator unit 530, but may be formed separately therefrom. The active layer 581 may include at least multiple quantum wells. Continuous light may be generated when an electric current is injected to the active layer 581. Another layer may be included between the first conductivity type semiconductor layer 503 and the active layer 581, and/or between the second conductivity type semiconductor layer 509 and the active layer 581. For example, an optical confinement layer may be arranged. Further, a grating layer may be included. In this case, the semiconductor laser unit 580 may be a DFB laser for outputting light of a 1.3-μm band. The oscillation wavelength may be in a 1.55-μm band, or may be in other wavelength bands. Further, the semiconductor laser unit 580 is not limited to the DFB laser, and may be a DBR laser. An interface between a waveguide layer 507 of the waveguide unit 540 to be described later and the active layer 581 of the semiconductor laser unit 580 may be made by butt joint connection.

The waveguide unit 540 may include the first conductivity type semiconductor layer 503, the waveguide layer 507, and the second conductivity type semiconductor layer 509, which may be arranged on the substrate 501. The first conductivity type semiconductor layer 503 and the second conductivity type semiconductor layer 509 of the waveguide unit 540 may be formed in the same layers as the first conductivity type semiconductor layer 503 and the second conductivity type semiconductor layer 509 of the modulator unit 530, but may be formed separately therefrom. The waveguide layer 507 may be a bulk semiconductor layer. Another layer may be included between the first conductivity type semiconductor layer 503 and the waveguide layer 507 and/or between the second conductivity type semiconductor layer 509 and the waveguide layer 507. For example, an optical confinement layer may be included. An interface between the waveguide layer 507 of the waveguide unit 540 and an optical functional layer 505 of the modulator unit 530 may be made by butt joint connection.

A mesa structure 521 extends from the first facet 523 to reach the second facet 525. A buried layer 513 may be arranged on side surfaces of the mesa structure 521 in the second direction D2. In other words, the semiconductor laser unit 580 and the waveguide unit 540 include the mesa structure 521.

The semiconductor laser unit 580 may include a laser trench portion 589. The laser trench portion 589 may be a part dug from the surface of the buried layer 513 to reach the first conductivity type semiconductor layer 503. The laser trench portion 589 may not reach the waveguide unit 540. Further, the laser trench portion 589 may not reach the first facet 523. The semiconductor laser unit 580 may include a first laser electrode 585 and a second laser electrode 587. The first laser electrode 585 may be electrically and physically connected to the first conductivity type semiconductor layer 503 in a bottom surface of the laser trench portion 589. The second laser electrode 587 may be arranged from an upper portion of the mesa structure 521 to an upper portion of the buried layer 513. The second laser electrode 587 may be electrically and physically connected to the second conductivity type contact layer 511 at the upper portion of the mesa structure 521. The first laser electrode 585 and the second laser electrode 587 each may have a rectangular shape in plan view, but the present invention is not limited thereto.

An optical semiconductor device in which a modulator and a semiconductor laser may be integrated in one substrate, and at the time of drive of the optical semiconductor device, a high-frequency electric signal may be applied to the modulator. Meanwhile, a DC current may be injected (DC voltage may be applied) to the semiconductor laser. At this time, when the electric signal applied to the modulator is transmitted to the semiconductor laser and thus the laser light is modulated, this may not be preferred in terms of optical characteristics. In the fifth example implementation, the waveguide unit 540 may be arranged between the modulator unit 530 and the semiconductor laser unit 580. The waveguide unit 540 allows a distance to be secured between the modulator unit 530 and the semiconductor laser unit 580, and thus electrical cross-talks may be reduced. Moreover, no second conductivity type contact layer 511 may be arranged in the waveguide unit 540 in order to increase an electric resistance between the modulator unit 530 and the semiconductor laser unit 580.

The optical semiconductor device may include a high resistance region 590. In the first example implementation, the high resistance region 90 extends from the first facet 23 to reach the second facet 25, and hence the first region 71 and the second region 72 may be electrically isolated from each other. However, in the fifth example implementation, the high resistance region 590 reaches the second facet 525, but does not reach the first facet 523. Instead, the high resistance region 590 may be arranged in a region of the waveguide unit 540 so as to cross a region between two side surfaces of the optical semiconductor device in the second direction D2 (that is, from one end portion to another end portion in the second direction D2). That is, as illustrated in FIG. 18, the high resistance region 590 may have a T-shape in plan view. With this configuration, in the region of the modulator unit 530, the first conductivity type semiconductor layer 503 may be divided into two regions of a first region 571 below the mesa structure 521 and a second region 572 below a second pad electrode 517C.

Moreover, the high resistance region 590 arranged in the waveguide unit 540 also may have an effect of enhancing electrical insulation between the modulator unit 530 and the semiconductor laser unit 580. As illustrated in FIG. 19, the first conductivity type semiconductor layer 503 may be arranged from the modulator unit 530 to reach the semiconductor laser unit 580. In some cases, electrical cross-talks may be generated via the first conductivity type semiconductor layer 503. In the fifth example implementation, the high resistance region 590 allows electrical isolation between the first conductivity type semiconductor layer 503 of the modulator unit 530 and the first conductivity type semiconductor layer 503 of the semiconductor laser unit 580. Further, as illustrated in FIG. 20, in the mesa structure 521, the high resistance region 590 reaches a lower surface of the waveguide layer 507. In this case, although the detailed semiconductor multilayer structure is not shown for the sake of description, for example, when a semi-insulating semiconductor layer (for example, an optical confinement layer) may be arranged below the waveguide layer 507, the high resistance region 590 may be arranged to reach a lower surface of the semi-insulating semiconductor layer. That is, the high resistance region 590 may be arranged so that a semiconductor layer having the same conductivity type may be prevented from being continuously arranged between the modulator unit 530 and the semiconductor laser unit 580 in a region within the mesa structure 521 and on the substrate 501 side with respect to the waveguide layer 507. As illustrated in FIG. 20, the thickness of the high resistance region 590 in the third direction D3 may be large only in the region of the mesa structure 521. In other words, the thickness of the high resistance region 590 arranged below the buried layer 513, including the high resistance region 590 arranged in the modulator unit 530, may be smaller than that of the high resistance region 590 arranged in the mesa structure 521. However, the present invention is not limited thereto, and the thickness of the high resistance region 590 arranged below the mesa structure 521 may be kept in the entire region.

The fifth example implementation may be combined with the high resistance regions described in the above-mentioned embodiments and modification examples.

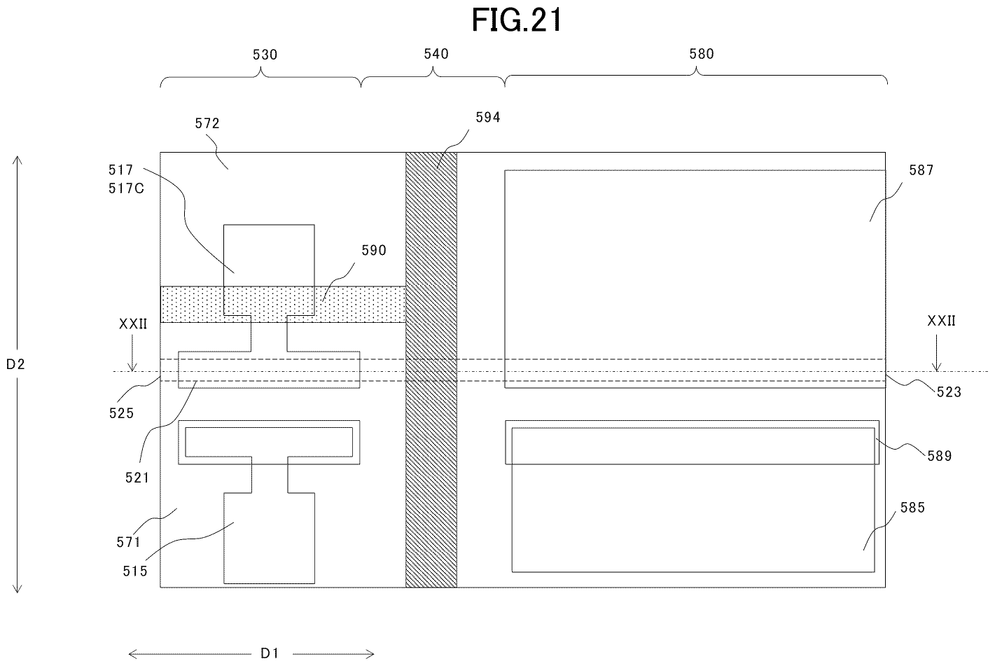

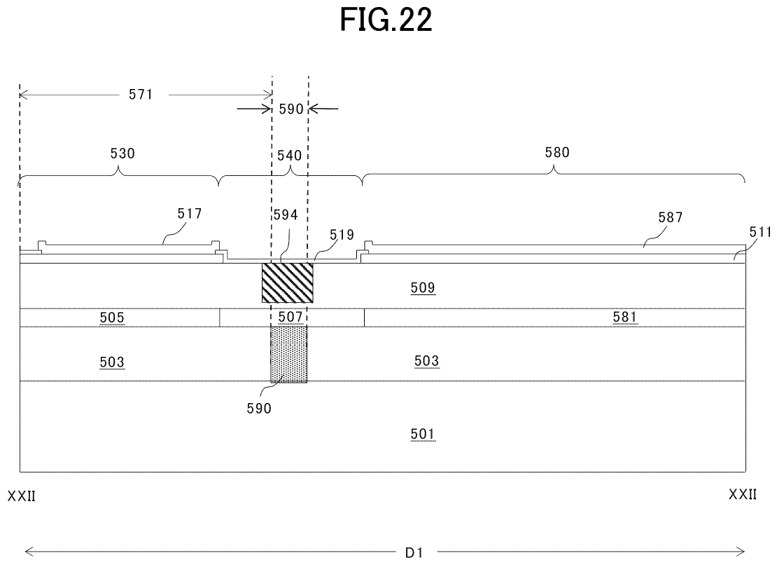

FIG. 21 is a top view of an optical semiconductor device according to a modification example of the fifth example implementation. FIG. 22 is a cross-sectional view for schematically illustrating a cross section taken along the line XXII-XXII of FIG. 21. The difference from the fifth example implementation resides in including an upper-side high resistance region 594.

The upper-side high resistance region 594 may be arranged in the waveguide unit 540 in plan view. The upper-side high resistance region 594 may be arranged to cross a region between the two side surfaces of the optical semiconductor device. As illustrated in FIG. 22, the upper-side high resistance region 594 may be arranged in the second conductivity type semiconductor layer 509. An upper surface of the upper-side high resistance region 594 may be substantially flush with the upper surface of the semiconductor multilayer. In this case, the upper surface of the upper-side high resistance region 594 may be flush with an upper surface of the second conductivity type semiconductor layer 509. When the second conductivity type contact layer 511 may be arranged in the waveguide unit 540, the upper surface of the upper-side high resistance region 594 may be flush with an upper surface of the second conductivity type contact layer 511. The upper-side high resistance region 594 may be formed by implanting impurity ions typified by, for example, proton into the second conductivity type semiconductor layer 509 from the surface of the semiconductor multilayer. A positional accuracy of proton implantation may be lower than that of semiconductor multilayer growth. Entrance of proton into the waveguide layer 507 is not preferred in terms of optical characteristics. Accordingly, a lower surface of the upper-side high resistance region 594 may not reach the waveguide layer 507. However, in some implementations, the lower surface of the upper-side high resistance region 594 may be desired to be flush with an upper surface of the waveguide layer 507.

The upper-side high resistance region 594 can restrict a current path via the second conductivity type semiconductor layer 509. As a result, the parasitic capacitance may be further reduced and electrical cross-talks between the modulator unit 530, and the semiconductor laser unit 580 may be further reduced.

In the above-mentioned embodiments, description may have been given assuming that the first conductivity type may be the “n” type and the second conductivity type may be the “p” type, but the present invention is not limited thereto. The first conductivity type may be the “p” type and the second conductivity type may be the “n” type. Further, description has been given assuming that the optical functional layer may be the absorption layer, but the optical functional layer may be an active layer for generating light in accordance with a voltage signal applied thereto. Further, in the description above, the high resistance region may have a shape obtained by combining straight lines, but the present invention is not limited thereto. The high resistance region may have a shape including a curved line in plan view.

In the present invention, in the optical semiconductor device in which the first conductivity type semiconductor layer, the optical functional layer, and the second conductivity type semiconductor layer may be grown above the insulating semiconductor layer, and which may include the first electrode connected to the first conductivity type semiconductor layer and the second electrode connected to the second conductivity type semiconductor layer, the parasitic capacitance of the electrode arranged above the first conductivity type semiconductor layer may be reduced, and a high-frequency characteristic may be improved. The embodiments of the present invention achieve this by the following configuration: the optical semiconductor device may include the first electrode connected to the first conductivity type semiconductor layer and the second electrode connected to the second conductivity type semiconductor layer, and the first region and the second region may be divided by the outer edge of the high resistance region in plan view. The second region excluding the high resistance region may be electrically isolated from the first region, and hence the parasitic capacitance caused by the electrode overlapping the second region may be reduced. In other words, at the time of actual drive, the influence of the parasitic capacitance caused by the electrode overlapping the second region may be reduced. The upper surface of the high resistance region may be arranged on the substrate side (insulating semiconductor layer side) with respect to the lower surface of the optical functional layer in the stacking direction of the semiconductor layers. The high resistance region may be formed by diffusing second conductivity type or insulating impurities in the first conductivity type semiconductor layer. As another example, the high resistance region may be formed by removing a part of the first conductivity type semiconductor layer, and arranging a second conductivity type or insulating semiconductor layer in the removed region. The optical functional layer may include the mesa structure. The buried layer may be arranged on the side surfaces of the mesa structure, and the high resistance region may be arranged below the buried layer. The high resistance region may extend from an incident facet to an exit facet of the optical semiconductor device in plan view. The high resistance region may have a U-shape, an L-shape, or a T-shape in plan view. The interface between the high resistance region and the first region may overlap the bridge electrode included in the first electrode and/or the second electrode in plan view. Further, the outer edge of the high resistance region may divide the first conductivity type semiconductor layer into, in addition to the first region that is electrically connected to the optical functional layer and the second region that is electrically connected thereto, the third region may not be electrically connected to the optical functional layer. When at least a part of the first electrode overlaps the first region in plan view, a parasitic capacitance caused by the first electrode may be reduced. The second region may include a region surrounded by the high resistance region and the facet and/or the side surface of the optical semiconductor device in plan view. The optical semiconductor device may include the modulator unit including the optical functional layer, the semiconductor laser unit, and the waveguide unit connecting the modulator unit and the semiconductor laser unit to each other. The high resistance region may be arranged in the modulator unit. Further, the high resistance region may be arranged to cross a region between the two side surfaces of the optical semiconductor device in the waveguide unit in plan view, and the high resistance region of the waveguide unit and the high resistance region of the modulator unit may form the second region of the first conductivity type semiconductor layer that is not electrically connected to the optical functional layer.

In a first implementation, according to at least one aspect of the present disclosure, an optical semiconductor device includes an insulating semiconductor layer; a first conductivity type semiconductor layer arranged above the insulating semiconductor layer; an optical functional layer arranged above the first conductivity type semiconductor layer, the optical functional layer forming a mesa structure; a second conductivity type semiconductor layer arranged above the optical functional layer; a first electrode including a first pad electrode configured to receive an electric signal as input, the first electrode being connected to the first conductivity type semiconductor layer; and a second electrode including a second pad electrode configured to receive an electric signal as input, the second electrode being connected to the second conductivity type semiconductor layer, wherein the first conductivity type semiconductor layer includes a first region, a second region, and a high resistance region overlapping at least a part of the second region in plan view, wherein the first region overlaps, in plan view, an entire region in plan view of the first pad electrode, wherein the second region overlaps, in plan view, an entire region in plan view of the second pad electrode, wherein the high resistance region is arranged so as to avoid the optical functional layer in plan view, and wherein the high resistance region has an outer edge which divides the first region and the second region in plan view.

In a second implementation, alone or in combination with the first implementation, the according to another aspect of the present disclosure, the high resistance region has an upper surface positioned on the insulating semiconductor layer side with respect to a lower surface of the optical functional layer.

In a third implementation, alone or in combination with one or more of the first and second implementations, according to another aspect of the present disclosure, the optical semiconductor device further includes a buried layer arranged on a side surface of the mesa structure in a direction perpendicular in plan view to a direction in which the mesa structure extends, and the high resistance region is arranged below the buried layer.

In a fourth implementation, alone or in combination with one or more of the first through third implementations, according to another aspect of the present disclosure, the first electrode further includes: a first contact electrode connected to the first conductivity type semiconductor layer; and a first bridge electrode connecting the first contact electrode and the first pad electrode to each other, the first bridge electrode is shorter than the first pad electrode in a direction in which the mesa structure extends, and an outer edge of the high resistance region on the mesa structure side overlaps the first bridge electrode in plan view.

In a fifth implementation, alone or in combination with one or more of the first through fourth implementations, according to another aspect of the present disclosure, the second electrode further includes: a second contact electrode connected to the second conductivity type semiconductor layer; and a second bridge electrode connecting the second contact electrode and the second pad electrode to each other, the second bridge electrode is shorter than the second pad electrode in a direction in which the mesa structure extends, and an outer edge of the high resistance region on the mesa structure side overlaps the second bridge electrode in plan view.

In a sixth implementation, alone or in combination with one or more of the first through fifth implementations, according to another aspect of the present disclosure, the optical semiconductor device further includes an incident facet and an output facet, and the high resistance region extends from the incident facet to the output facet.

In a seventh implementation, alone or in combination with one or more of the first through sixth implementations, according to another aspect of the present disclosure, the second region is entirely the high resistance region.

In an eighth implementation, alone or in combination with one or more of the first through seventh implementations, according to another aspect of the present disclosure, the high resistance region has one of an L-shape or a U-shape in plan view.

In a ninth implementation, alone or in combination with one or more of the first through eighth implementations, according to another aspect of the present disclosure, the first conductivity type semiconductor layer further includes: a third region electrically connected to the optical functional layer; and a second high resistance region overlapping at least a part of the first region in plan view, the second high resistance region is arranged so as to avoid the optical functional layer in plan view, an upper surface of the second high resistance region is arranged on the insulating semiconductor layer side with respect to a lower surface of the optical functional layer, and the second high resistance region has an outer edge which divides the third region and the first region in plan view.

In a tenth implementation, alone or in combination with one or more of the first through ninth implementations, according to another aspect of the present disclosure, an upper surface of the high resistance region is flush with or higher than an interface between the first conductivity type semiconductor layer and the buried layer as viewed from the insulating semiconductor layer.

In an eleventh implementation, alone or in combination with one or more of the first through tenth implementations, according to another aspect of the present disclosure, the optical semiconductor device further includes: a first facet at which light is input to the optical functional layer; and a second facet at which output light is output from the optical functional layer, the first conductivity type semiconductor layer is electrically connected to the optical functional layer in the first region, and the second region is surrounded by at least a part of the outer edge of the high resistance region, the first facet, the second facet, and a side surface intersecting with the first facet and the second facet.

In a twelfth implementation, alone or in combination with one or more of the first through eleventh implementations, according to another aspect of the present disclosure, the buried layer is an insulating semiconductor.

In a thirteenth implementation, alone or in combination with one or more of the first through twelfth implementations, according to another aspect of the present disclosure, the optical semiconductor device further includes: a modulator unit including the optical functional layer; a semiconductor laser unit; and a waveguide unit connecting the modulator unit and the semiconductor laser unit to each other, the high resistance region includes: a first part which is arranged in the modulator unit and extends in parallel to the mesa structure; and a second part which is arranged in the waveguide unit and extends in a direction orthogonal to the mesa structure in plan view, the second part connecting to the first part, and the first region and the second region are divided in plan view by an outer edge of the first part and an outer edge of the second part.

In a fourteenth implementation, alone or in combination with one or more of the first through thirteenth implementations, according to another aspect of the present disclosure, the mesa structure is arranged across a region from the modulator unit to the semiconductor laser unit, and a height of a high resistance region of the modulator unit is lower than a height of the high resistance region arranged in the mesa structure of the waveguide unit as viewed from the insulating semiconductor layer.

In a fifteenth implementation, alone or in combination with one or more of the first through fourteenth implementations, according to another aspect of the present disclosure, the waveguide unit includes a waveguide layer between the first conductivity type semiconductor layer and the second conductivity type semiconductor layer, the second conductivity type semiconductor layer is arranged across a region from the modulator unit to the semiconductor laser unit, and the second conductivity type semiconductor layer of the waveguide unit includes an upper-side high resistance region having a lower surface positioned on an upper side with respect to an upper surface of the waveguide layer.

In a sixteenth implementation, alone or in combination with one or more of the first through fifteenth implementations, according to another aspect of the present disclosure, the mesa structure includes the second conductivity type semiconductor layer, and the buried layer is arranged also on a side surface of the second conductivity type semiconductor layer in the mesa structure.

In a seventeenth implementation, alone or in combination with one or more of the first through sixteenth implementations, according to another aspect of the present disclosure, the second conductivity type semiconductor layer is arranged above the mesa structure, and the buried layer is arranged on a side portion of the mesa structure and between the first conductivity type semiconductor layer and the second conductivity type semiconductor layer.

In an eighteenth implementation, alone or in combination with one or more of the first through seventeenth implementations, according to another aspect of the present disclosure, the optical semiconductor device further includes a buried layer arranged on a side surface of the mesa structure in a direction perpendicular in plan view to a direction in which the mesa structure extends, and a trench portion extending from an upper surface of the buried layer to reach the first conductivity type semiconductor layer, and the first contact electrode is connected to the first conductivity type semiconductor layer in a bottom surface of the trench portion.

While there have been described what are at present considered to be certain implementations of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical semiconductor device, comprising:
an insulating semiconductor layer;
a first conductivity type semiconductor layer arranged above the insulating semiconductor layer;
an optical functional layer arranged above the first conductivity type semiconductor layer, the optical functional layer forming a mesa structure;
a second conductivity type semiconductor layer arranged above the optical functional layer;
a first electrode including a first pad electrode configured to receive an electric signal as input, the first electrode being connected to the first conductivity type semiconductor layer; and
a second electrode including a second pad electrode configured to receive an electric signal as input, the second electrode being connected to the second conductivity type semiconductor layer,
wherein the first conductivity type semiconductor layer includes a first region, a second region, and a high resistance region overlapping at least a part of the second region in plan view,
wherein the first region overlaps, in plan view, an entire region in plan view of the first pad electrode,
wherein the second region overlaps, in plan view, an entire region in plan view of the second pad electrode,
wherein the high resistance region is arranged so as to avoid the optical functional layer in plan view, and
wherein the high resistance region has an outer edge which divides the first region and the second region in plan view.

2. The optical semiconductor device according to claim 1, wherein the high resistance region has an upper surface positioned on the insulating semiconductor layer side with respect to a lower surface of the optical functional layer.

3. The optical semiconductor device according to claim 1, further comprising a buried layer arranged on a side surface of the mesa structure in a direction perpendicular in plan view to a direction in which the mesa structure extends,
wherein the high resistance region is arranged below the buried layer.

4. The optical semiconductor device according to claim 1,
wherein the first electrode further includes:
a first contact electrode connected to the first conductivity type semiconductor layer; and
a first bridge electrode connecting the first contact electrode and the first pad electrode to each other,
wherein the first bridge electrode is shorter than the first pad electrode in a direction in which the mesa structure extends, and
wherein an outer edge of the high resistance region on the mesa structure side overlaps the first bridge electrode in plan view.

5. The optical semiconductor device according to claim 1,
wherein the second electrode further includes:
a second contact electrode connected to the second conductivity type semiconductor layer; and
a second bridge electrode connecting the second contact electrode and the second pad electrode to each other,
wherein the second bridge electrode is shorter than the second pad electrode in a direction in which the mesa structure extends, and
wherein an outer edge of the high resistance region on the mesa structure side overlaps the second bridge electrode in plan view.

6. The optical semiconductor device according to claim 1, further comprising an incident facet and an output facet,
wherein the high resistance region extends from the incident facet to the output facet.

7. The optical semiconductor device according to claim 1, wherein the second region is entirely the high resistance region.

8. The optical semiconductor device according to claim 1, wherein the high resistance region has one of an L-shape or a U-shape in plan view.

9. The optical semiconductor device according to claim 1,
wherein the first conductivity type semiconductor layer further includes:
a third region electrically connected to the optical functional layer; and
a second high resistance region overlapping at least a part of the first region in plan view,
wherein the second high resistance region is arranged so as to avoid the optical functional layer in plan view,
wherein an upper surface of the second high resistance region is arranged on the insulating semiconductor layer side with respect to a lower surface of the optical functional layer, and
wherein the second high resistance region has an outer edge which divides the third region and the first region in plan view.

10. The optical semiconductor device according to claim 3, wherein an upper surface of the high resistance region is flush with or higher than an interface between the first conductivity type semiconductor layer and the buried layer as viewed from the insulating semiconductor layer.

11. The optical semiconductor device according to claim 1, further comprising:
a first facet at which light is input to the optical functional layer; and
a second facet at which output light is output from the optical functional layer,
wherein the first conductivity type semiconductor layer is electrically connected to the optical functional layer in the first region, and
wherein the second region is surrounded by at least a part of the outer edge of the high resistance region, the first facet, the second facet, and a side surface intersecting with the first facet and the second facet.

12. The optical semiconductor device according to claim 3, wherein the buried layer is an insulating semiconductor.

13. The optical semiconductor device according to claim 1, further comprising:
a modulator unit including the optical functional layer;
a semiconductor laser unit; and
a waveguide unit connecting the modulator unit and the semiconductor laser unit to each other,
wherein the high resistance region includes:
a first part which is arranged in the modulator unit and extends in parallel to the mesa structure; and
a second part which is arranged in the waveguide unit and extends in a direction orthogonal to the mesa structure in plan view, the second part connecting to the first part, and
wherein the first region and the second region are divided in plan view by an outer edge of the first part and an outer edge of the second part.

14. The optical semiconductor device according to claim 13,
wherein the mesa structure is arranged across a region from the modulator unit to the semiconductor laser unit, and
wherein a height of a high resistance region of the modulator unit is lower than a height of the high resistance region arranged in the mesa structure of the waveguide unit as viewed from the insulating semiconductor layer.

15. The optical semiconductor device according to claim 13,
wherein the waveguide unit includes a waveguide layer between the first conductivity type semiconductor layer and the second conductivity type semiconductor layer,
wherein the second conductivity type semiconductor layer is arranged across a region from the modulator unit to the semiconductor laser unit, and
wherein the second conductivity type semiconductor layer of the waveguide unit includes an upper-side high resistance region having a lower surface positioned on an upper side with respect to an upper surface of the waveguide layer.

16. The optical semiconductor device according to claim 3,
wherein the mesa structure includes the second conductivity type semiconductor layer, and
wherein the buried layer is arranged also on a side surface of the second conductivity type semiconductor layer in the mesa structure.

17. The optical semiconductor device according to claim 3,
wherein the second conductivity type semiconductor layer is arranged above the mesa structure, and
wherein the buried layer is arranged on a side portion of the mesa structure and between the first conductivity type semiconductor layer and the second conductivity type semiconductor layer.

18. The optical semiconductor device according to claim 4, further comprising a buried layer arranged on a side surface of the mesa structure in a direction perpendicular in plan view to a direction in which the mesa structure extends, and
a trench portion extending from an upper surface of the buried layer to reach the first conductivity type semiconductor layer,
wherein the first contact electrode is connected to the first conductivity type semiconductor layer in a bottom surface of the trench portion.
